(19) United States
(12) Patent Application Publication
(10) Pub. No.: US 2026/0196270 A1
(43) Pub. Date: Jul. 9, 2026

(54) PROGRAM PULSE OVERDRIVE FOR PERFORMANCE GAIN IN A MEMORY DEVICE

(71) Applicant: Micron Technology, Inc., Boise, ID (US)

(72) Inventors: Yu-Chung Lien, San Jose, CA (US); Zhenming Zhou, San Jose, CA (US)

(21) Appl. No.: 19/012,432

(22) Filed: Jan. 7, 2025

(51) Int. Cl. G11C 16/10; G11C 16/04; G11C 16/08

(52) U.S. Cl. CPC G11C 16/10; G11C 16/0483; G11C 16/08

(57) ABSTRACT

A memory device includes a memory array with a plurality of blocks arranged across a plurality of wordlines, a row decoder, and control logic for programming cells on a wordline. The control logic initiates, on the wordline of the memory array, a programming operation to program one or more cells associated with the wordline. The control logic determines a programming offset for performing the programming operation. The control logic applies, to the row decoder, a programming pulse using a voltage level that is greater than a target programming voltage level by the programming offset. The voltage level that is greater than the target programming voltage level by the programming offset is applied to the one or more cells associated with the wordline during the programming operation.

### TECHNICAL FIELD

Embodiments of the disclosure relate generally to memory sub-systems, and more specifically, relate to program pulse overdrive for performance gain in a memory device of a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A depicts an example computing system that includes a memory sub-system, in accordance with some embodiments of the present disclosure.

FIG. 1B depicts a block diagram of an example memory device in communication with a memory sub-system controller of a memory sub-system, in accordance with some embodiments of the present disclosure.

FIG. 2 is a schematic of portions of an example array of memory cells as could be used in a memory of the type described with reference to FIG. 1B, in accordance with some embodiments of the present disclosure.

FIG. 3 is a diagram illustrating an example multi-dimensional memory array having multiple sub-blocks, in accordance with some embodiments of the present disclosure.

FIG. 4 is a diagram illustrating an example waveform with program pulse overdrive for programming cells that are located near to row decoding circuitry, in accordance with some embodiments of the present disclosure.

FIG. 5 is a diagram illustrating an example waveform with program pulse overdrive for programming cells that are located further from row decoding circuitry, in accordance with some embodiments of the present disclosure.

FIG. 6 is a flow diagram of an example method of implementing program pulse overdrive for performance gain in a memory device of a memory sub-system, in accordance with some embodiments of the present disclosure.

FIG. 7 is a block diagram of an example computer system in which embodiments of the present disclosure can operate.

### DETAILED DESCRIPTION

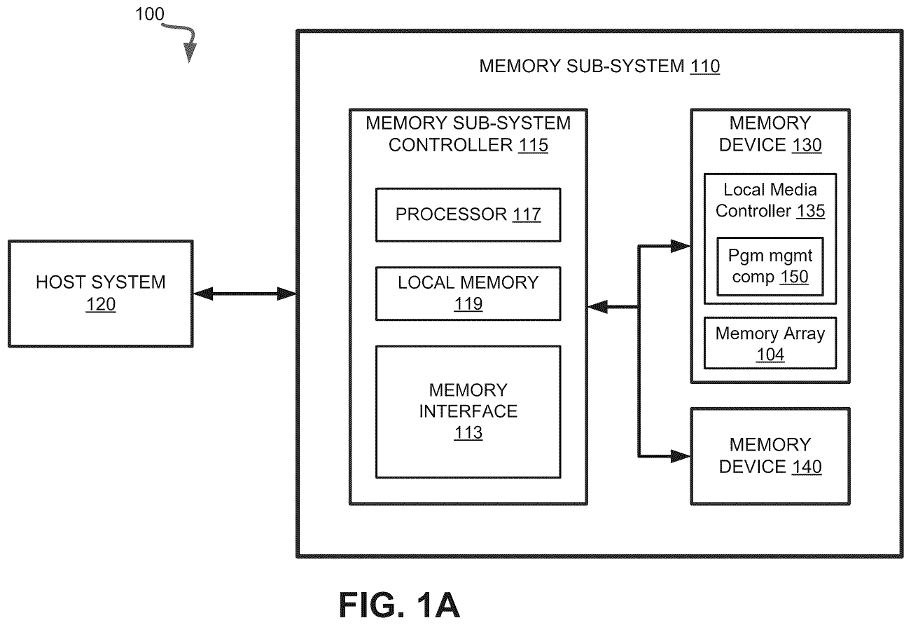

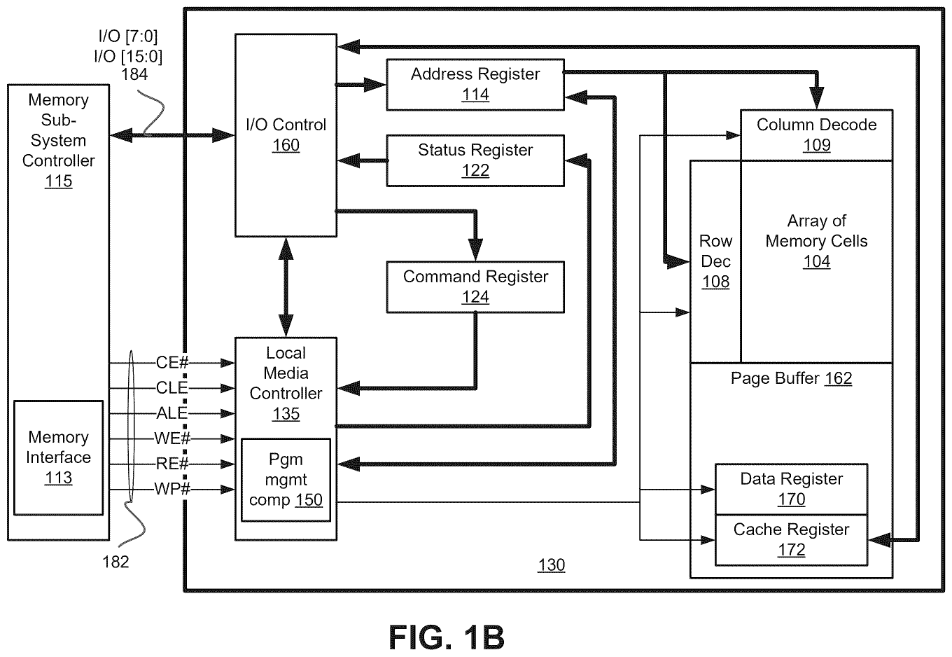

Aspects of the present disclosure are directed to implementing program pulse overdrive for performance gain in a memory device of a memory sub-system. A memory subsystem can be a storage device, a memory module, or a hybrid of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory subsystem.

A memory sub-system can include high density non-volatile memory devices where retention of data is desired when no power is supplied to the memory device. For example, NAND memory, such as 3D flash NAND memory, offers storage in the form of compact, high-density configurations. A non-volatile memory device is a package of one or more dice, each including one or more planes. For some types of non-volatile memory devices (e.g., NAND memory), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bit lines) and rows (also hereinafter referred to as wordlines). A wordline can refer to one or more rows of memory cells of a memory device that are used with one or more bit lines to generate the address of each of the memory cells. The intersection of a bit line and wordline constitutes the address of the memory cell. A block hereinafter refers to a unit of the memory device that is used to store data and can include a group of memory cells, a wordline group, a wordline, or individual memory cells.

One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. Each data block can include a number of sub-blocks, where each sub-block is defined by an associated pillar (e.g., a vertical conductive trace) extending from a shared bitline. Since the sub-blocks can be accessed separately (e.g., to perform program or read operations), the data block can include a structure to selectively enable the pillar associated with a certain sub-block, while disabling the pillars associated with other sub-blocks. In some embodiments, this structure includes one or more select gate devices positioned at either or both ends of each pillar. Depending on a control signal applied, these select gate devices can either enable or disable the conduction of signals through the pillars. In some embodiments, the select gates devices associated with each pillar in the data block are controlled separately. Newer memory architectures have an ever-increasing number of sub-blocks (e.g., 4, 6, 8, or more sub-blocks per block), in order to increase the potential for parallel memory access operations.

A memory access operation can be performed on a cell by issuing a memory access command to a memory device on which the cell is located (e.g., the memory device that houses the block on which the cell is located). In some instances, the command can include instructions for programming the cell (e.g., instructions to write data to the cell). A host device can generate the command (e.g., the program command) and transmit the program command to a memory sub-system within which the cell is located. The components of the memory sub-system can determine an address of the cell (e.g., the intersecting bit line and wordline that indicate the location of the cell). Components of the memory sub-system (e.g., row decoding circuitry) can transmit the program command to the address that corresponds to the cell using a specific programming voltage (also referred to as a programming pulse). The programming pulse can have a magnitude (i.e., a programming voltage level) that differs from an operating voltage level of the cell, which can be applied to the cell to maintain the standard functionality of the cell. In some instances, the row decoding circuitry can apply the programming pulse to the wordline associated with the cell. An amount of time that is needed for the pulse applied to the wordline to surpass the operating voltage level and rise to the programming voltage level can experience delays. In some instances, the delay can be attributed to varying degrees of resistance (e.g., RC resistance) that the program pulse experiences when traveling from the row decoding circuitry to the cell, for example.

In some instances, the resistance can arise as a result of fabrication challenges associated with the memory device, which can impact memory device performance. For example, the structural makeup of the memory device can include one or more metal layers (e.g., in and between blocks). In some instances, the thickness of the metal layers can become uneven across different blocks. The quantity of metal layers and inconsistent thickness can lead to a number of issues during operation of the memory device, such as increased resistance. In some instances, the degree of resistance that the pulse experiences can depend on the location of the cell (e.g., whether the cell is associated with a bit line that is located near to the row decoding circuitry or a bit line that is located further from the row decoding circuitry). For example, the degree of resistance that the program pulse experiences when applied to a cell that is located near to the row decoding circuitry can be less than the degree of resistance that the program pulse experiences when applied to a cell that is located further from the row decoding circuitry. The resistance that the program pulse experiences when applied to a cell that is located further from the row decoding circuitry can also increase the amount of time that is needed for the program pulse to be applied to the cell. The delay in applying the program pulse to the cell can result in delayed execution of the program command, thereby increasing the latency associated with programming the cell.

Aspects of the present disclosure address the above and other deficiencies by implementing program pulse overdrive for performance gain in a memory device of a memory sub-system. A memory sub-system can receive, from a host device, a command to program a specific cell on the memory device. The memory sub-system can determine an overdrive programming pulse to be applied to a wordline on which the cell is located. The overdrive programming pulse can correspond to a voltage level that is greater than an operating voltage level of the cell and a programming voltage level that is typically applied to program cells on the wordline. When the overdrive programming pulse is implemented, the voltage level of the pulse that is applied to the wordline surpasses both the operating voltage level and the programming voltage level that are associated with the cell, and rises to a voltage level that is equal to that of the overdrive programming pulse. Due to phenomena that contribute to the decrease of voltage levels over time (e.g., resistance, use of the memory device, etc.), the voltage level of the overdrive programming pulse can decrease and stabilize (e.g., plateau) at a particular voltage level. Specifically, the voltage level of the overdrive programming pulse can decrease to and plateau at the programming voltage level that is associated with the cell. In some instances, the voltage level of the overdrive programming pulse can decrease to the programming voltage level faster than a pulse applied to the wordline can rise to the programming voltage level. Therefore, implementing the overdrive programming pulse can decrease the amount of time that is needed for the voltage level of the pulse that is applied to the wordline to stabilize at the programming voltage level. The cells that are associated with bit lines that are located further from the row decoding circuitry can receive the programming pulse faster when the overdrive programming pulse is applied to the wordline associated with the cell. As such, program commands can be executed on cells that are further from the row decoder with reduced latency, thereby increasing the efficiency and the performance of the memory device.

Advantages of this approach include, but are not limited to, improved performance in the memory sub-system. In particular, implementing an overdrive programming pulse reduces an amount of time that is typically needed for a pulse that is applied to a wordline to stabilize at the programming voltage level that is typically used to program cells on the wordline. Further, implementing the overdrive programming pulse can boost the programming efficiency of the memory device by reducing the amount of time that is needed for a voltage level of the pulse that is applied to the wordline to equal the programming voltage level.

FIG. 1A illustrates an example computing system 100 that includes a memory subsystem 110 in accordance with some embodiments of the present disclosure. The memory subsystem 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Small Computer System Interface (SCSI), Serial Attached SCSI (SAS), a double data rate (DDR) memory bus, a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the physical host interface (e.g., PCIe or CXL interface). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include not-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory subsystem controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device 130 having control logic (e.g., local controller 135) on the die and a controller (e.g., memory sub-system controller 115) for media management within the same memory device package. An example of a managed memory device is a managed NAND (MNAND) device. Memory device 130, for example, can represent a single die having some control logic (e.g., local media controller 135) embodied thereon. In some embodiments, one or more components of memory sub-system 110 can be omitted.

In one embodiment, the memory sub-system 110 includes a memory interface 113 that is responsible for handling interactions of memory sub-system controller 115 with the memory devices of memory sub-system 110, such as memory device 130. For example, the memory interface 113 can send memory access commands corresponding to requests received from host system 120 to memory device 130, such as program commands, read commands, or other commands. In addition, the memory interface 113 can receive data from memory device 130, such as data retrieved in response to a read command or a confirmation that a program command was successfully performed. In some embodiments, the memory sub-system controller 115 includes at least a portion of the memory interface 113. For example, the memory sub-system controller 115 can include a processor 117 (processing device) configured to execute instructions stored in local memory 119 for performing the operations described herein.

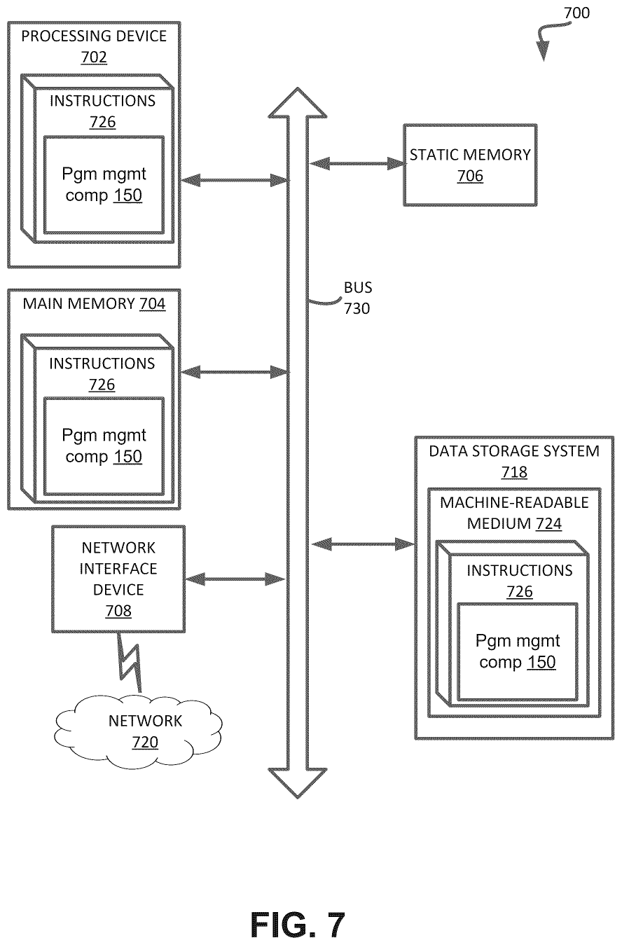

In one embodiment, local media controller 135 of memory device 130 includes program management component 150 (referred to pgm mgmt comp 150 in FIGS. 1A, 1B, 7). Program management component 150 can apply overdrive programming pulses to different wordlines in the memory array 104 of memory device 130. For example, when executing a program command on a cell in a given block of the memory device 130, program management component 150 can identify the programming voltage level that is typically applied to program the cell and determine an overdrive programming voltage level that surpasses the programming voltage level. The program management component 150 can provide the determined overdrive programming voltage level to the address circuitry associated with the memory device 130 (e.g., row decoding circuitry, column decoding circuitry). In some instances, the program management component 150 can also provide the address circuitry associated with the memory device 130 with instructions to apply the overdrive programming voltage level to a wordline on which the cell is located. The program management component 150 can cause the program operation to be performed on the cell using the overdrive programming voltage level. Further details regarding the operations of the program management component 150 are described below.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device. In one embodiment, memory sub-system controller 115 includes memory interface 113.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bit line). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 109 are provided to decode address signals. Address signals are received and decoded to access the array of memory cells 104. For each program command, an address signal can indicate an address that corresponds to the cell to be programmed. Specifically, the address signal can indicate the intersecting wordline and bit line where the cell is located in the array of memory cells 104. In some instances, the row decode circuitry 108 (and/or the column decode circuitry 109) can be in communication with the program management component 150. As such, the row decode circuitry 108 (and/or the column decode circuitry 109) can receive instructions to apply an overdrive programming pulse to a wordline in the array of memory cells 104 to program one or more cells on the wordline.

Memory device 130 also includes input/output (I/O) control circuitry 160 to manage input of commands, addresses and data to the memory device 130 as well as output of data and status information from the memory device 130. An address register 114 is in communication with I/O control circuitry 160, row decode circuitry 108, and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115 (i.e., the local media controller 135 is configured to perform access operations such as read operations, programming operations and/or erase operations on the array of memory cells 104). The local media controller 135 is in communication with row decode circuitry 108 and column decode circuitry 109 to control the row decode circuitry 108 and column decode circuitry 109 in response to the addresses. In one embodiment, local media controller 135 includes program management component 150, which can implement program pulse overdrive for performance gain in memory array 104, as described herein.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer 162 of the memory device 130. The page buffer 162 may further include sensing devices (not shown in FIG. 1B) to sense a data state of a memory cell of the array of memory cells 104 (e.g., by sensing a state of a data line connected to that memory cell). A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 182. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 182 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 184 and outputs data to the memory subsystem controller 115 over I/O bus 184.

For example, the commands may be received over input/output (I/O) pins [7:0] of I/O bus 184 at I/O control circuitry 160 and may then be written into command register 124. The addresses may be received over input/output (I/O) pins [7:0] of I/O bus 184 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated into distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

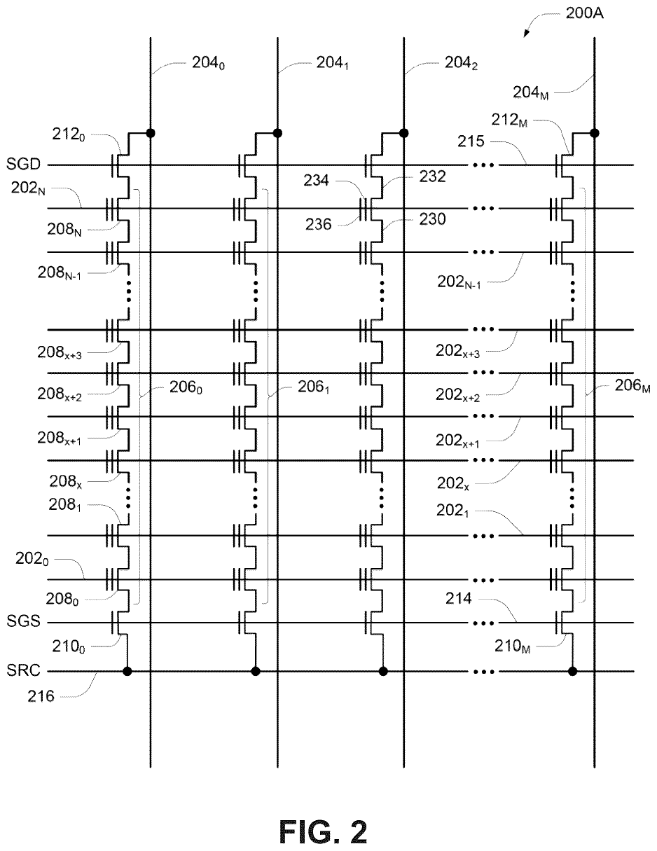

FIG. 2 is a schematic of portions of an array of memory cells 104, such as a NAND memory array, as could be used in a memory of the type described with reference to FIG. 1B, according to an embodiment. Memory array 104 includes access lines, such as wordlines 202₀ to 202_{N}, and data lines, such as bit lines 204₀ to 204_{M}. The wordlines 202 can be connected to global access lines (e.g., global wordlines), not shown in FIG. 2, in a many-to-one relationship. In some embodiments, memory array 104 can be formed over a semiconductor that, for example, can be conductively doped to have a conductivity type, such as a p-type conductivity (e.g., to form a p-well) or an n-type conductivity (e.g., to form an n-well).

Memory array 104 can be arranged in rows (each corresponding to a wordline 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bit line 204 for the corresponding NAND string 206. For example, the drain of select gate 212₀ can be connected to the bit line 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bit line 204. A control gate of each select gate 212 can be connected to select line 215.

The memory array 104 in FIG. 2 can be a quasi-two-dimensional memory array and can have a generally planar structure (e.g., where the common source 216, NAND strings 206, and bit lines 204 extend in substantially parallel planes). Alternatively, the memory array 104 in FIG. 2 can be a three-dimensional memory array (e.g., where NAND strings 206 can extend substantially perpendicular to a plane containing the common source 216 and to a plane containing the bit lines 204 that can be substantially parallel to the plane containing the common source 216).

Typical construction of memory cells 208 includes a data-storage structure 234 (e.g., a floating gate, charge trap) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bit line 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bit lines 204 (e.g., bit lines 204₀, 204₂, 204₄, etc.) can be one physical page of the memory cells 208 (e.g., even memory cells) while memory cells 208 commonly connected to wordline 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2, it is apparent from the figure that the bit lines 204 of the array of memory cells 104 can be numbered consecutively from bit line 204₀ to bit line 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

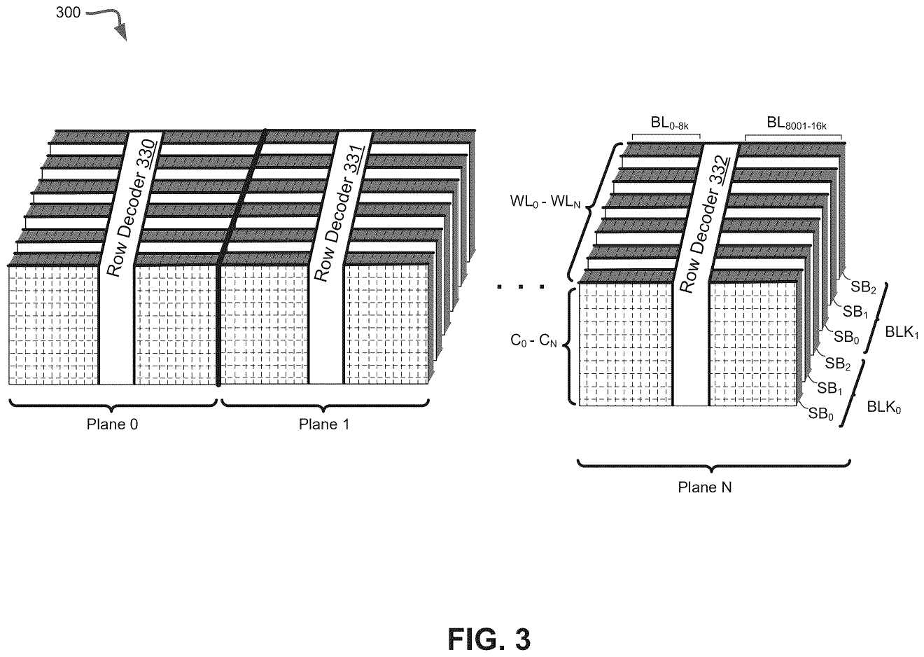

FIG. 3 is a diagram illustrating an example multi-dimensional memory array having multiple sub-blocks, in accordance with some embodiments of the present disclosure. Memory array 300 can be representative of an array of memory cells (e.g., array of memory cells 104). As illustrated, memory array 300 can include a plurality of planes, such as planes 0-N. While three planes are depicted in FIG. 3, a memory array can include more or fewer planes. Each plane can include a subset of blocks, such as blocks BLK₀-BLK₁. While FIG. 3 illustrates two blocks, a plane can include more or fewer blocks depending on the implementation. Each block can include associated control circuitry that allows the block to be accessed separately from one other, such that concurrent memory access operations can be performed in parallel on different blocks. A block can include a plurality of sub-blocks, such as sub-blocks SB₀-SB₂. While FIG. 3 illustrates two sub-blocks per block, a block can include more or fewer sub-blocks depending on the implementation. Each sub-block can include a plurality of cells, such as cells C₀-C_{N}, to which data can be written by way of a program command. In some implementations, the horizontal lines that span memory array 300 (e.g., along the X-axis of a three-dimensional coordinate system) can be representative of wordlines (e.g., wordlines WL₀ to WL_{N}) and the vertical lines (e.g., along the Y-axis of a three-dimensional coordinate system) can be representative of bit lines (e.g., bit lines BL_{0-8K} to BL_{8001-16K}). Each plane can store a specific amount of data (e.g., 16K). As such, the bit lines on either side of the row decoder associated with the plane can store a portion of the specific amount of data that the plane can store. For example, with respect to Plane N, the bit lines that are located on a first side of the row decoder 332 can store between 0-8K data while the bit lines that are located on a second side of the row decoder can store between 8001-16K data. The intersection of a wordline and a bit line can indicate a cell address.

The cell address can be used to execute a program command. Specifically, row decoding circuitry (e.g., row decoders 330-332) can apply a pulse to the wordline associated with the cell in order to program the cell. As described above, during fabrication of the memory device, metal films can be diffused through memory array 300 to form access lines for the cells located on the memory array. In some instances, there is the possibility that the thickness of the metal layers becomes uneven across the different blocks of the memory arrays. The varying degrees of thickness of the metal layers can impact the resistance that the pulse experiences when traveling from the row decoding circuitry to the cell to be programmed. As such, program management component 150 can implement program pulse overdrive to reduce the amount of time needed for the voltage level of the pulse applied to the wordline to equal the programming voltage level that is typically applied to program cells on the wordline. The magnitude of the pulse that is applied to the wordline can surpass (e.g., by a programming offset) the magnitude of the programming pulse that is typically applied to program cells on the wordline. In some instances, the magnitude of the programming offset can be determined based on a variety of factors. For example, when the largest programming offset is implemented, it can take less time for the voltage level of the cells that experience the pulse to rise to the overdrive programming voltage level but can take longer for the voltage level of the cells that experience the pulse to dissipate to the programming voltage level. Implementing the largest programming offset can be beneficial when the cells to be programmed are located further from the row decoding circuitry because the voltage level of the cells that are located further from the row decoding circuitry can rise to the overdrive programming voltage level quickly. In another example, when the smallest programming offset is implemented, it can take longer for the voltage level of the cells that experience the pulse to rise to the overdrive programming voltage level but can take less time for the voltage level of the cells that experience the pulse to dissipate to the programming voltage level. Implementing the smallest programming offset can be beneficial when the cells to be programmed are located near to the row decoding circuitry because, in some instances, the pulse that is applied to the wordline can experience less resistance and the voltage level of the cells can rise to the overdrive programming voltage level quickly. Therefore, determining the magnitude of the programming offset can include balancing the benefits that the cells near to and further from the row decoding circuitry will experience. The implementation of program pulse overdrive can reduce an amount of time needed to program cells, thereby improving the performance of the memory device, as will be described in more detail below.

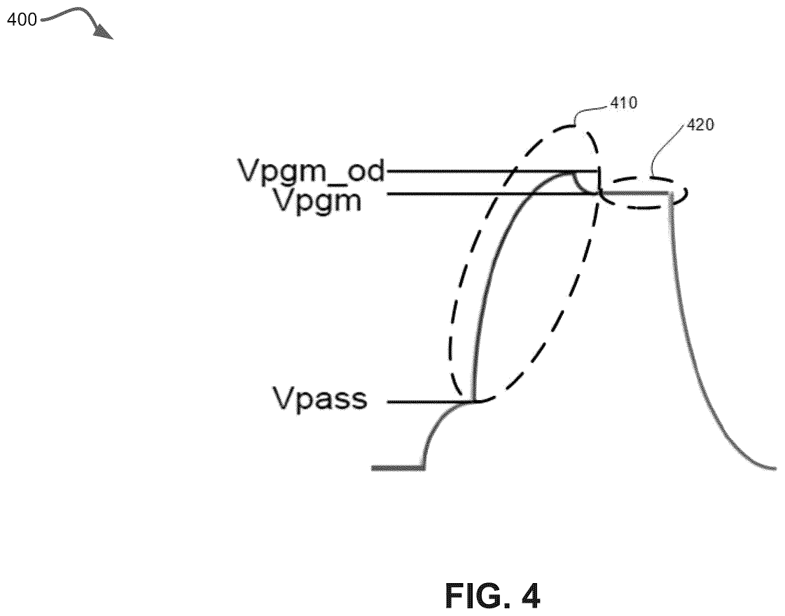

FIG. 4 is a diagram illustrating an example waveform with program pulse overdrive for programming cells that are located near to row decoding circuitry, in accordance with some embodiments of the present disclosure. Example waveform 400 illustrates the voltage level trajectory of a pulse that is applied to a wordline (e.g., wordlines 202₀ to 202_{N}). Vₚₐₛₛ can correspond to an operating voltage level that is applied to the wordline to maintain the standard functionality of a cell. In some instances, cells that are not programmed during the execution of a program command maintain Vₚₐₛₛ. V_{pgm} can correspond to the programming voltage level that is typically applied to a wordline to program cells on the wordline. V_{pgm_od} can correspond to the overdrive programming voltage level that is applied to a wordline to reduce an amount of time that is need for the voltage level of the pulse applied to the wordline to equal that of the programming voltage level.

When a pulse is applied to a wordline, the voltage level of the pulse can rise to Vₚₐₛₛ. If the cell that experiences the pulse is not the cell to be programmed, then the voltage level of the pulse that is applied to the cell remains at Vₚₐₛₛ. If a cell that is located near the row decoding circuitry (e.g., a cell that is associated with a bit line that is located near the row decoding circuitry) experiences the pulse and is the cell to be programmed, then the voltage level of the pulse rises to V_{pgm_od}. Element 410 illustrates the trajectory of the voltage level that is experienced by the cell that is located near the row decoding circuitry and is the cell to be programmed. Over time, the voltage level of the pulse that is applied to the wordline can decrease from V_{pgm_od} to V_{pgm}. The voltage level of the pulse that is applied to the wordline can stabilize at V_{pgm}, as illustrated by element 420. The voltage level trajectory that is experienced by a cell that is located further from the row decoding circuitry (e.g., a cell that is associated with a bit line that is located further from the row decoding circuitry) and is the cell to be programmed is discussed below.

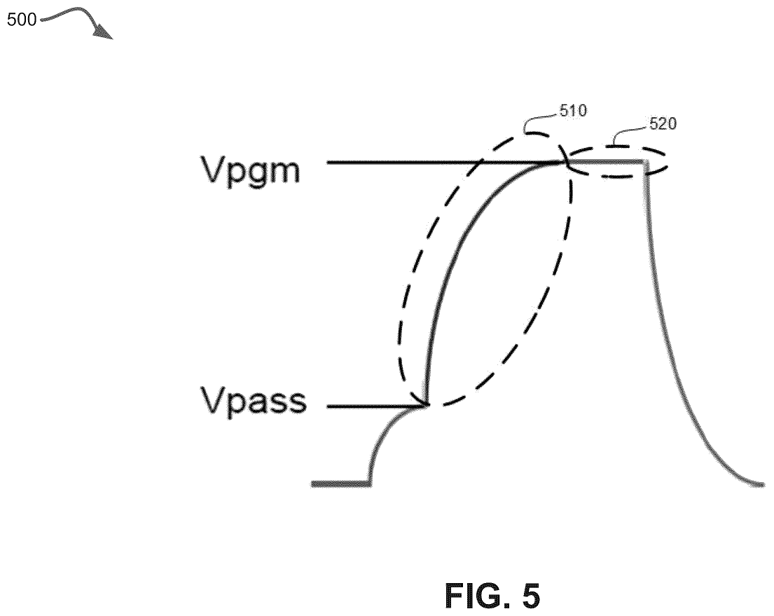

FIG. 5 is a diagram illustrating an example waveform with program pulse overdrive for programming cells that are located further from row decoding circuitry, in accordance with some embodiments of the present disclosure. Example waveform 500 illustrates the voltage level trajectory of a pulse that is applied to a wordline (e.g., wordlines 202₀ to 202_{N}). Vₚₐₛₛ can correspond to an operating voltage level that is applied to the wordline to maintain the standard functionality of a cell. In some instances, cells that are not programmed during the execution of a program command maintain Vₚₐₛₛ. V_{pgm} can correspond to the programming voltage level that is typically applied to a wordline to program cells on the wordline.

As described in connection with FIG. 4, the voltage level of the pulse that is applied to the wordline (e.g., to cells that are located near to the row decoding circuitry) can decrease from V_{pgm_od} to V_{pgm}, and can stabilize at V_{pgm}. However, when a pulse, the magnitude of which is the overdrive programming voltage level, is applied to the wordline, the voltage level of a cell that is located further from the row decoding circuitry can rise from Vₚₐₛₛ to V_{pgm} faster than in instances where the overdrive programming pulse is not applied to the wordline. The voltage level of the cell that is located further from the row decoding circuitry can achieve V_{pgm} with fewer signal delays. As a result, the cell can be programmed with fewer time delays, thereby boosting the programming efficiency of the memory device. Element 510 illustrates the voltage level trajectory of a pulse that is applied to a cell that is located further from the row decoding circuitry when the overdrive programming pulse is implemented. The voltage level that is experienced by the cells that are located further from the row decoding circuitry can stabilize at V_{pgm}, as illustrated by element 520.

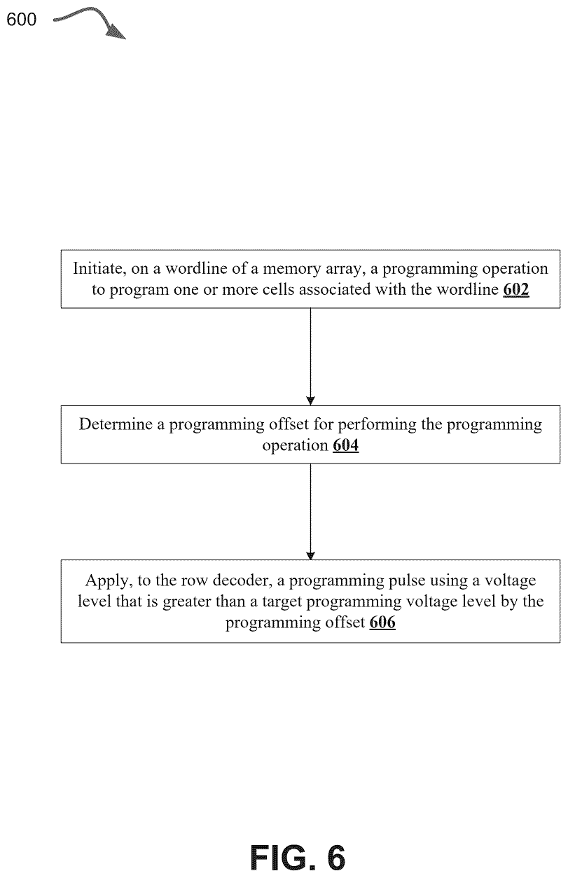

FIG. 6 is a flow diagram of an example method of implementing program pulse overdrive for performance gain in a memory device of a memory sub-system, in accordance with some embodiments of the present disclosure. The method 600 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 600 is performed by program management component 150 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 602, the processing logic can initiate, on a wordline of a memory array, a programming operation to program one or more cells associated with the wordline. In some instances, the programming operation can include data to be written to a cell that is located on the wordline, for example.

At operation 604, the processing logic can determine a programming offset for performing the programming operation. The programming offset can correspond to the difference between the magnitude of an overdrive programming voltage level and the magnitude of a target programming voltage level. The target programming voltage level can correspond to a voltage level that is typically applied to the wordline to program cells on the wordline. The overdrive programming voltage level can surpass the target programming voltage level by the programming offset. In some instances, the magnitude of an overdrive programming pulse that is used to apply the overdrive programming voltage level to the wordline can be determined based on the amount of resistance that the overdrive programming voltage level will experience when the overdrive programming pulse is applied to the wordline associated with the one or more cells. The overdrive programming pulse can be applied to the one or more cells associated with the wordline during the programming operation.

At operation 606, the processing logic can apply, to the row decoder, a programming pulse using a voltage level that is greater than a target programming voltage level by the programming offset. Row decoding circuitry (e.g., row decode circuitry 108) can be used to apply a pulse to a wordline in order to execute a program command. When a pulse is applied to the wordline, a voltage level associated with a cell that is not to be programmed (e.g., to which data will not be written during the execution of a program command) can rise from an initial programming voltage level to a programming pass voltage level. In some instances, the programming pass voltage level can correspond to an operating voltage level that is applied to the cell to maintain the standard functionality of the cell. The voltage level of the cell that is not to be programmed can remain at the programming pass voltage level. However, the voltage level of a cell that is to be programmed (e.g., to which data will be written during the execution of a program command) can rise from the programming pass voltage level to the overdrive programming voltage level.

The cells that are to be programmed and that are located near to the row decoder (e.g., cells that are associated with a bit line that is located near to the row decoder) can experience the overdrive programming voltage level. The cells that are to be programmed and that are located further from the row decoder (e.g., cells that are associated with a bit line that is located further from the row decoder) can experience the target programming voltage level based on the dissipation of the overdrive programming voltage level over time.

FIG. 7 illustrates an example machine of a computer system 700 within which a set of instructions, for causing the machine to perform any one or more of the methodologies discussed herein, can be executed. In some embodiments, the computer system 700 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to program management component 150 or local media controller 135 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 700 includes a processing device 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a data storage system 718, which communicate with each other via a bus 730.

Processing device 702 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 702 can also be one or more special-purpose processing devices such as an application specific integrated circuit (ASIC), a field programmable gate array (FPGA), a digital signal processor (DSP), network processor, or the like. The processing device 702 is configured to execute instructions 726 for performing the operations and steps discussed herein. The computer system 700 can further include a network interface device 708 to communicate over the network 720.

The data storage system 718 can include a machine-readable storage medium 724 (also known as a computer-readable medium) on which is stored one or more sets of instructions 726 or software embodying any one or more of the methodologies or functions described herein. The instructions 726 can also reside, completely or at least partially, within the main memory 704 and/or within the processing device 702 during execution thereof by the computer system 700, the main memory 704 and the processing device 702 also constituting machine-readable storage media. The machine-readable storage medium 724, data storage system 718, and/or main memory 704 can correspond to the memory sub-system 110 of FIG. 1A.

In one embodiment, the instructions 726 include instructions to implement functionality corresponding to the program management component 150 of FIG. 1A. While the machine-readable storage medium 724 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising a plurality of blocks arranged across a plurality of wordlines, each block comprising a plurality of memory cells;
a row decoder operatively coupled to the memory array; and
control logic, operatively coupled with the memory array, to perform operations comprising: initiating, on a wordline of the plurality of wordlines of the memory array, a
programming operation to program one or more cells associated with the wordline; determining a programming offset for performing the programming operation; and applying, to the row decoder, a programming pulse using a voltage level that is
greater than a target programming voltage level by the programming offset,
wherein the voltage level that is greater than the target programming voltage level by the programming offset is applied to the one or more cells associated with the wordline during the programming operation.

2. The memory device of claim 1,
wherein the voltage level is increased from an initial programming voltage to a programming pass voltage, wherein the programming pass voltage is applied to programmed cells that are associated with the wordline; and
wherein the programming pass voltage is increased to the target programming voltage level.

3. The memory device of claim 2,
wherein the voltage level is increased from the initial programming voltage to the programming pass voltage at a first programming time; and
wherein the programming pass voltage is increased to the target programming voltage level at a second programming time.

4. The memory device of claim 3, wherein cells, of the one or more cells associated with the wordline, that are nearest to the row decoder experience, at the first programming time, a programming voltage that exceeds the target programming voltage by the programming offset.

5. The memory device of claim 3, wherein cells, of the one or more cells associated with the wordline, that are furthest from the row decoder experience, at the second programming time, the target programming voltage based on a dissipation of the programming pulse over time.

6. The memory device of claim 3, wherein the voltage level of the programming pulse stabilizes to the target programming voltage level between the first programming time and the second programming time.

7. The memory device of claim 1, wherein a magnitude of the programming offset is based on a level of resistance that the programming pulse experiences when applied to the wordline.

8. A method comprising:
initiating, on a wordline of a plurality of wordlines of a memory array, a programming operation to program one or more cells associated with the wordline;
determining a programming offset for performing the programming operation; and
applying, to a row decoder, a programming pulse using a voltage level that is greater than a target programming voltage level by the programming offset,
wherein the voltage level that is greater than the target programming voltage level by the programming offset is applied to the one or more cells associated with the wordline during the programming operation.

9. The method of claim 8, wherein a magnitude of the programming offset is based on a level of resistance that the programming pulse experiences when applied to the wordline.

10. The method of claim 8, wherein cells, of the one or more cells on the wordline, that are nearest to the row decoder experience, at a first programming time, a programming voltage that exceeds the target programming voltage by the programming offset.

11. The method of claim 8, wherein cells, of the one or more cells associated with the wordline, that are furthest from the row decoder experience, at a second programming time, the target programming voltage based on a dissipation of the programming pulse over time.

12. The method of claim 8,
wherein the voltage level is increased from an initial programming voltage to a programming pass voltage, wherein the programming pass voltage is applied to programmed cells that are associated with the wordline; and
wherein the programming pass voltage is increased to the target programming voltage level.

13. The method of claim 12,
wherein the voltage level is increased from the initial programming voltage to the programming pass voltage at a first programming time; and
wherein the programming pass voltage is increased to the target programming voltage level at a second programming time.

14. The method of claim 13, wherein applying the programming pulse to the row decoder stabilizes the target programming voltage between the first programming time and the second programming time.

15. A non-transitory computer readable storage medium comprising instructions that, when executed by a processing device, cause the processing device to perform operations comprising:
initiating, on a wordline of a plurality of wordlines of a memory array, a programming operation to program one or more cells associated with the wordline;
determining a programming offset for performing the programming operation; and
applying, to a row decoder, a programming pulse using a voltage level that is greater than a target programming voltage level by the programming offset,
wherein the voltage level that is greater than the target programming voltage level by the programming offset is applied to the one or more cells associated with the wordline during the programming operation.

16. The non-transitory computer readable storage medium of claim 15, wherein cells, of the one or more cells on the wordline, that are nearest to the row decoder experience, at a first programming time, a programming voltage that exceeds the target programming voltage by the programming offset.

17. The non-transitory computer readable storage medium of claim 16, wherein cells, of the one or more cells associated with the wordline, that are furthest from the row decoder experience, at a second programming time, the target programming voltage based on a dissipation of the programming pulse over time.

18. The non-transitory computer readable storage medium of claim 15,
wherein the voltage level is increased from an initial programming voltage to a programming pass voltage, wherein the programming pass voltage is applied to programmed cells that are associated with the wordline; and
wherein the programming pass voltage is increased to the target programming voltage level.

19. The non-transitory computer readable storage medium of claim 18,
wherein the voltage level is increased from the initial programming voltage to the programming pass voltage at a first programming time; and
wherein the programming pass voltage is increased to the target programming voltage level at a second programming time.

20. The non-transitory computer readable storage medium of claim 19, wherein the voltage level of the programming pulse stabilizes to the target programming voltage level between the first programming time and the second programming time.
